(19) United States
(12) Patent Application Publication
(10) Pub. No.: US 2024/0090213 A1
(43) Pub. Date: Mar. 14, 2024

(54) SACRIFICIAL LAYER FOR FORMING MERGED HIGH ASPECT RATIO CONTACTS IN 3D NAND MEMORY DEVICE

(71) Applicant: Applied Materials, Inc., Santa Clara, CA (US)

(72) Inventors: Jialiang WANG, Santa Clara, CA (US); Soonil LEE, Santa Clara, CA (US); Eswaranand VENKATASUBRAMANIAN, Santa Clara, CA (US); Chang Seok KANG, San Jose, CA (US); Sanjay G. KAMATH, Fremont, CA (US); Abhijit B. MALLICK, Fremont, CA (US); Srinivas GUGGILLA, San Jose, CA (US); Amy CHILD, Gansevoort, NY (US); Sung-Kwan KANG, San Jose, CA (US); Balasubramanian PRANATHARTHIHARAN, Santa Clara, CA (US)

(21) Appl. No.: 18/238,954

(22) Filed: Aug. 28, 2023

Related U.S. Application Data
(60) Provisional application No. 63/462,238, filed on Apr. 26, 2023.
(60) Provisional application No. 63/404,834, filed on Sep. 8, 2022.

(51) Int. Cl. H10B 41/35; H01L 21/02; H01L 21/3065; H01L 21/67; H10B 43/10

(52) U.S. Cl. CPC H10B 41/35; H01L 21/02164; H01L 21/02274; H01L 21/3065; H01L 21/67063; H10B 43/10; H10B 80/00

(57) ABSTRACT

A method of forming a semiconductor memory device includes simultaneously filling a top portion of a first high aspect ratio (HAR) structure and a top portion a second HAR structure with a silicon-containing sacrificial layer by a cycle of a deposition process and an etch process, wherein the first HAR structure has a critical dimension (CD) of between 150 nm and 250 nm, and the second HAR structure has a CD of between 250 nm and 400 nm.

### CROSS-REFERENCE TO RELATED APPLICATIONS

This application claims priority to U.S. Provisional Application Ser. No. 63/462,238, filed Apr. 26, 2023, and No. 63/404,834 filed Sep. 8, 2022, each of which is herein incorporated by reference in its entirety.

### BACKGROUND

### Field

The present disclosure generally relates to memory devices, and methods of manufacturing the same, and more particularly, to device structures and methods of forming high aspect ratio contacts in three-dimensional (3D) memory devices.

### Description of the Related Art

As the number of vertical stacks of memory cells in three dimensional (3D) NAND memory devices increases, height of the vertical stacks increases, thus increasing aspect ratio of contacts formed through the vertical stacks. As aspect ratios of the contacts increase, cost for fabricating such high aspect ratio contacts (HARCs) (e.g., memory holes, word line contacts, peripheral contacts with underlying complementary metal-oxide semiconductor (CMOS) circuits) significantly increases since different types of HARCs (e.g., with different sizes or features, such as filling materials) may need to be fabricated separately. To decrease fabrication cost, different types of HARCs can be merged (e.g., fabricated together) by covering some HARCs with a sacrificial layer while fabricating other HARCs by thermal processing.

Therefore, there is a need for sacrificial layers that can be filled and removed for different types of HARCs and can be thermally stable at high temperature.

### SUMMARY

Embodiments of the present disclosure provide a method of forming a semiconductor memory device. The method includes simultaneously filling a top portion of a first high aspect ratio (HAR) structure and a top portion a second HAR structure with a silicon-containing sacrificial layer by a cycle of a deposition process and an etch process, wherein the first HAR structure has a critical dimension (CD) of between 150 nm and 250 nm, and the second HAR structure has a CD of between 250 nm and 400 nm.

Embodiments of the present disclosure provide a method of forming a semiconductor memory device. The method includes filing a top portion of a high aspect ratio (HAR) opening with a silicon-containing sacrificial layer by a cycle of a deposition process and an etch process, and widening a critical dimension (CD) of the HAR opening.

Embodiments of the present disclosure provide a method of forming a semiconductor memory device. The method includes performing a hole patterning process, the hole patterning process comprising forming a memory hole and contact holes through a stacking mold of alternating oxide layers and nitride layers, performing a first filling process, the first filling process comprising filling the memory hole and the contact holes with a carbon-containing sacrificial layer, performing a first removal process, the first removal process comprising selectively removing the carbon-containing sacrificial layers from the contact holes, performing a second filling process, the second filling process comprising filling the contact holes with an amorphous silicon-containing sacrificial layer, and performing a cell formation process, the cell formation process comprising forming memory cells along the memory hole.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic view of an example 3D NAND memory structure according to one embodiment.

FIG. 2 depicts a process flow diagram of a method of patterning holes in a semiconductor structure according to one embodiment.

FIGS. 3A, 3B, 3C, 3D, 3E, 3F, 3G, and 3H are cross-sectional views of a portion of a semiconductor structure corresponding to various states of the method of FIG. 2.

FIG. 4 depicts a process flow diagram of a method 400 for forming a memory hole, word line contacts, and peripheral contacts in a semiconductor structure formed by the method of FIG. 2.

FIGS. 5A, 5B, 5C, 5D, 5E, 5F, 5G, 5H, 5I, 5I′, 5J, 5J′, 5K, 5L, 5M, 5M′, 5N, 5N′, 6A, 6B, 6C, and 6D are cross-sectional views of a portion of a semiconductor structure corresponding to various states of the method of FIG. 4.

FIG. 7 is a schematic view of an exemplary HDP-CVD system 700 according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The embodiments described herein provide methods for forming different types of high aspect ratio contacts (HARCs) in three-dimensional (3D) NAND memory devices. In the examples described herein, memory cells are fabricated while contact holes, in which word line contacts, common source contacts with underlying common source lines, and peripheral contacts with underlying complementary metal-oxide semiconductor (CMOS) circuits, are covered by a sacrificial layer. The contact holes for word line contacts, common source contacts, and peripheral contacts, which have different critical dimensions (CDs), are simultaneously filled from the top of the contact holes. The sacrificial layer is formed of silicon (e.g., amorphous silicon) and thermally stable during fabrication of memory cells that requires a high temperature anneal. The sacrificial layer is formed by a deposition/etch/deposition (DED) process, including a high density plasma chemical vapor deposition (HPD-CVD) process, such that the sacrificial layer covers top portions of the contact holes.

The sacrificial layer formed of silicon (e.g., amorphous silicon) used to fill holes for word line contacts and peripheral contacts has etch selectivity from a carbon (C)-containing sacrificial layer used to fill memory holes, dielectric layers (e.g., silicon oxide (SiO₂) or silicon nitride (Si₃N₄), or metal layers (e.g., tungsten (W)).

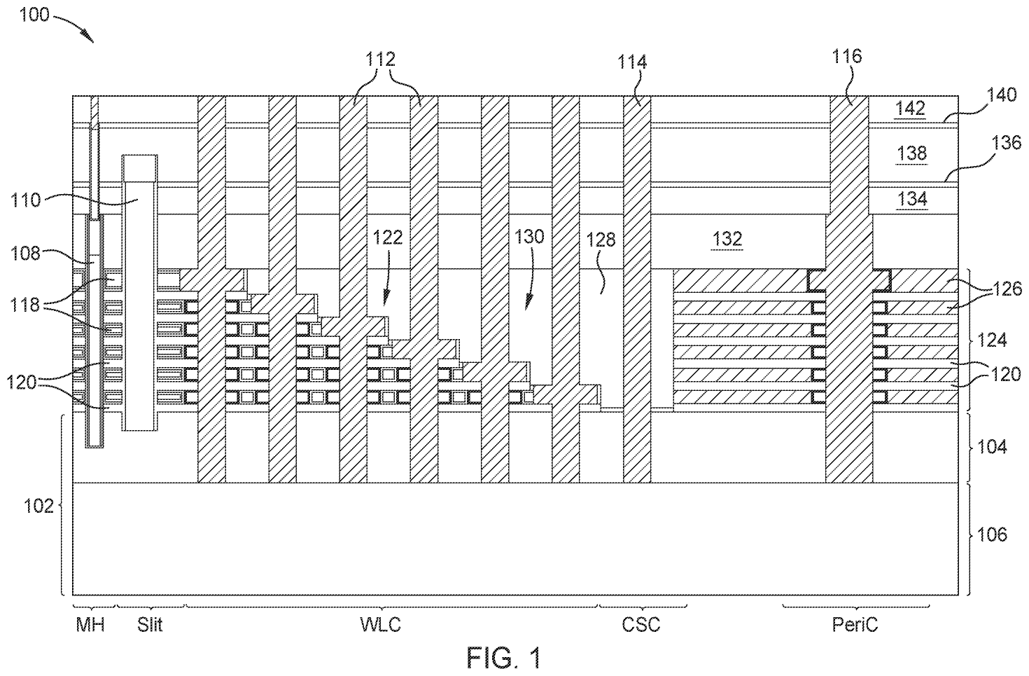

FIG. 1 is a schematic view of an example 3D NAND memory structure 100. The 3D NAND memory structure 100 is formed on a substrate 102 that includes a common source line (CSL) layer 104 and a CMOS circuit layer 106 formed therewithin. The 3D NAND memory structure 100 includes a memory hole (MH) region, in which memory holes 108 are formed, a slit region in which a gate slit line 110 is formed, a word line contact (WLC) region in which word line contacts 112 are formed, a common source contact (CSC) region in which a common source contact 114 is formed, and a peripheral contact (PeriC) region in which peripheral contacts 116 are formed. The 3D NAND memory structure 100 includes a stack of alternating word line layers 118 and oxide layers 120 in the direction perpendicular to the major surface of the substrate 102 to form a string of memory cells. An end of the stack of the word line layers 118 and the oxide layer 120 forms a staircase 122, such that each of the word line layers 118 can be connected to one of the word line contacts 112. In this way, in the 3D NAND memory structure 100, memory cells may be fabricated in a vertical direction along the memory hole 108, so that a memory capacity may be easily increased by stacking additional word line layers 118. The 3D NAND memory structure 100 further includes a stacking mold 124 of alternating oxide layers 120 and nitride layers 126 formed on the substrate 102. As described below in detail, the word line layers 118 are formed by removing the nitride layers 126 in the stacking mold 124 in the MH region, the slit region, and the WLC region, and then depositing a metal layer in the same place where the nitride layers 126 were removed.

The 3D NAND memory structure 100 further includes an insulator layer 128 filling an opening 130 adjacent to the staircase 122, an inter-layer dielectric (ILD) layer 132 over the stack of the word line layers and the oxide layer 120, the insulator layer 128, and the stacking mold 124, a dielectric layer 134 over the ILD layer 132, a dielectric layer 136 over the dielectric layer 134, a dielectric layer 138 over the dielectric layer 136, a dielectric layer 140 over the dielectric layer 138, and a dielectric layer 142 over the dielectric layer 140. The dielectric layers 134, 138, and 142 may be formed of silicon oxide (SiO₂). The dielectric layers 136 and 140 may be formed of silicon nitride (Si₃N₄) and act as chemical mechanical planarization (CMP) stop layers.

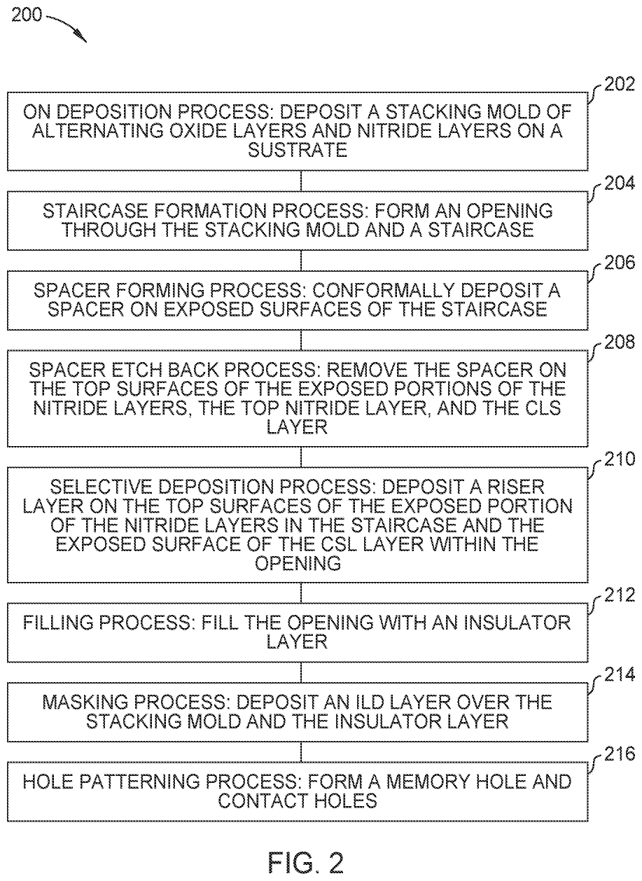

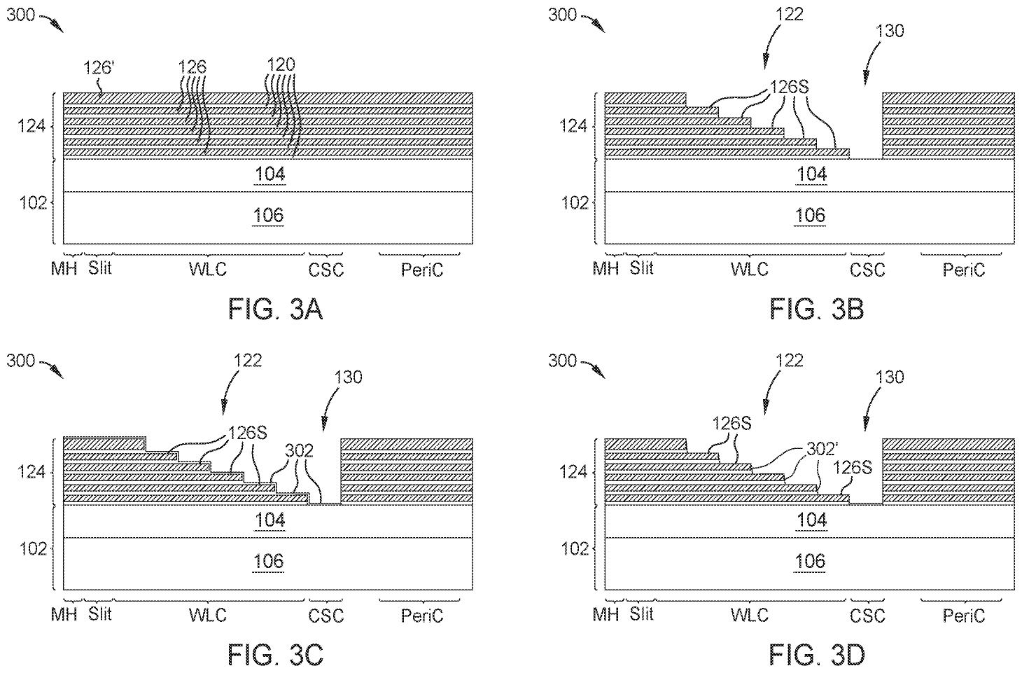

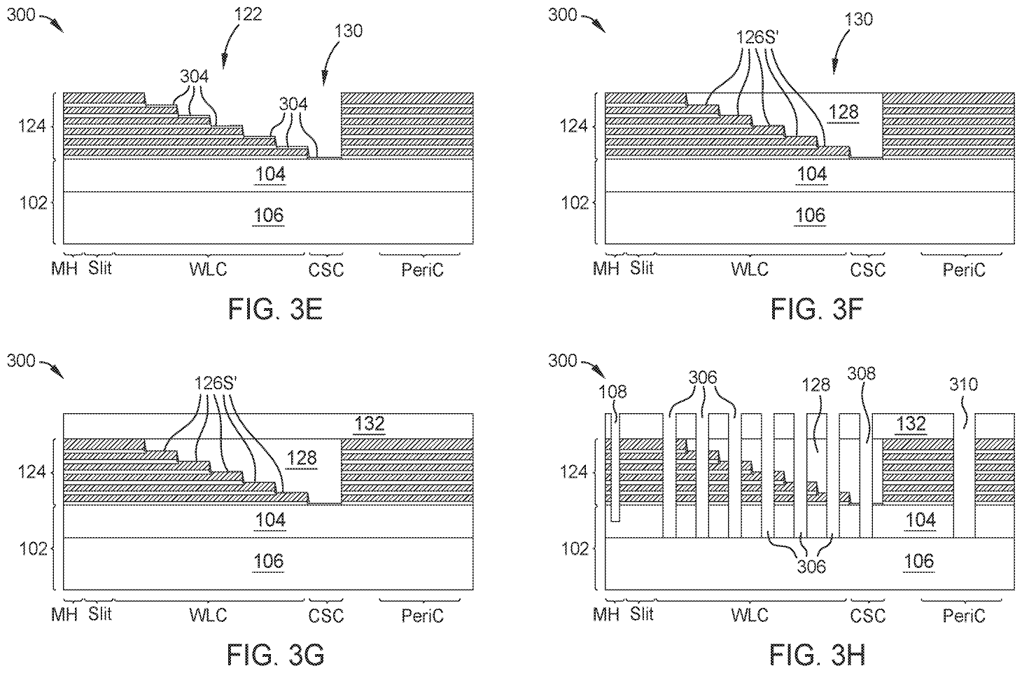

FIG. 2 depicts a process flow diagram of a method 200 of patterning holes in a semiconductor structure 300. FIGS. 3A, 3B, 3C, 3D, 3E, 3F, 3G, and 3H are cross-sectional views of a portion of the semiconductor structure 300 corresponding to various states of the method 200. It should be understood that FIGS. 3A, 3B, 3C, 3D, 3E, 3F, 3G, and 3H illustrate only partial schematic views of the semiconductor structure 300, and the semiconductor structure 300 may contain any number of transistor sections and additional materials having aspects as illustrated in the figures. It should also be noted that although the method illustrated in FIG. 2 is described sequentially, other process sequences that include one or more operations that have been omitted and/or added, and/or has been rearranged in another desirable order, fall within the scope of the embodiments of the disclosure provided herein.

In the examples described herein, formation of a high aspect ratio (HAR) memory hole, a gate slit line, common source contacts, word line contacts, and peripheral contacts is described. However, the methods described herein can also be applied to fabrication of other types of HAR structures that may be holes or line patterns. Further in the examples described herein, memory cells are formed along a memory hole while contact holes are covered by a sacrificial layer. However, the methods described herein can also be applied to any pattering on one type of a HAR structure while other types of HAR structures are covered by a sacrificial layer.

The method 200 begins with block 202, in which an oxide nitride (ON) deposition process is performed to deposit a stacking mold 124 of alternating oxide layers 120 and nitride layers 126 on a substrate 102, as shown in FIG. 3A. The oxide layers 120 may be formed of silicon oxide (SiO₂), and the nitride layer 126 may be formed of silicon nitride (Si₃N₄). The substrate 102 includes a common source line (CSL) layer 104 and a CMOS circuit layer 106 formed therewithin. The semiconductor structure 300 includes a memory hole (MH) region, in which memory holes are to be formed, a slit region in which a gate slit line is to be formed, a word line contact (WLC) region in which word line contacts are to be formed, a common source contact (CSC) region in which a common source contact is to be formed, and a peripheral contact (PeriC) region in which peripheral contacts are formed.

A top nitride layer 126′ that is at the top of the stacking mold 124 is thicker than the remaining nitride layers 126, by a factor of between about 1.1 and about 2, for example, about 2. For example, the top nitride layer 126′ has a thickness of between about 17 nm and about 80 nm, the remaining nitride layers 126 each have a thickness T_{N} of between about 15 nm and 40 nm, and the oxide layers 120 each have a thickness of between about 10 nm and 30 nm. In the example shown in FIG. 3A, the number of pairs of the oxide layers 120 and the nitride layers 126 is six. However, the number of pairs of the oxide layers 120 and the nitride layers 126 may be larger than a few hundreds, for example, about 300. Thus, the stacking mold 124 of 300 pairs of the oxide layers 120 and the nitride layers 126 may have a height of between about 7.5 μm and about 21 μm, not including the top nitride layer 126′, and a height of between about 8 μm and about 21.5 μm, including the top nitride layer 126′ having a thickness of about 0.5 μm, for example, about 14 μm.

The ON deposition process in block 202 may include any appropriate deposition process, such as atomic layer deposition (ALD), chemical vapor deposition (CVD), physical vapor deposition (PVD), or the like.

In block 204, a staircase formation process is performed to form an opening 130 through the stacking mold 124 and a staircase 122 within the opening 130 in the WLC region and the CSC region, as shown in FIG. 3B. In the staircase 122, a portion 126S of each of the nitride layers 126 is exposed. The exposed portion 126S may have a critical dimension (CD) of between about 10 nm and about 100 nm.

The staircase formation process in block 204 may include any appropriate lithography and etch processes, such as photolithography.

In block 206, a spacer forming process is performed to conformally deposit a spacer 302 on exposed surfaces of the staircase 122 (i.e., top surfaces and sidewalls of the exposed portions 126S of the nitride layers 126, a top surface of the top nitride layer 126′, an exposed surface of the CSL layer 104 within the opening 130), as shown in FIG. 3C. The spacer 302 may be formed of silicon oxide (SiO₂) and have a thickness of between about 5 nm and about 50 nm.

The spacer forming process in block 206 may include any appropriate deposition process, such as atomic layer deposition (ALD).

In block 208, a spacer etch back process is performed to remove the spacer 302 on the top surfaces of the exposed portions 126S of the nitride layers 126, the top nitride layer 126′, and the CSL layer 104, as shown in FIG. 3D. As a result, the sidewall spacer 302′ on the sidewalls of the staircase 122 (i.e., sidewalls of the exposed portions 126S and the top nitride layer 126′) remains. The sidewall spacer 302′ prevents shortage between word lines to be formed. The sidewall spacer 302′ may have a thickness of between about 5 nm and about 50 nm.

The spacer etch back process in block 208 may include an anisotropic etch process such as reactive ion etching (RIE).

In block 210, a selective deposition process is performed to deposit a riser layer 304 on the top surfaces of the exposed portion 126S of the nitride layers 126 in the staircase 122 and the exposed surface of the CSL layer 104 within the opening 130, as shown in FIG. 3E. The riser layer 304 may be formed of silicon nitride (Si₃N₄) and have a thickness of between about 0.1 and about 1.9 times of the thickness T_{N} of the nitride layer 126 (between about 20 nm and about 40 nm). The riser layer 304 may be merged with the underlying exposed portion 126S of the nitride layer 126 to form a raised pad 126S′ (shown in FIG. 3F) having a thickness TNR of between about 1.1 and about 2.0 times of the thickness T_{N} of the nitride layer 126.

The selective deposition process in block 210 may include any appropriate deposition process, such as atomic layer deposition (ALD), by alternately supplying silicon-containing precursor, e.g., dichlorosilane (SiH₂Cl₂) and nitrogen-containing precursor, e.g., ammonia (NH₃). Silicon nitride (Si₃N₄) grows on hydrogen-terminated Si bonds on the etched surface of the exposed portion 126S of the nitride layer 126.

In block 212, a filling process is performed to fill the opening 130 with an insulator layer 128, as shown in FIG. 3F. The insulator layer 128 may be formed of silicon oxide (SiO₂). The filling process in block 212 may include any appropriate deposition process, such as atomic layer deposition (ALD), chemical vapor deposition (CVD), physical vapor deposition (PVD), or the like. After the filling process, the semiconductor structure 300 may be planarized, by use of a chemical mechanical planarization (CMP) process or an etch back of the insulator layer 128.

In block 214, a masking process is performed to deposit an inter-layer dielectric (ILD) layer 132 over the stacking mold 124 and the insulator layer 128, as shown in FIG. 3G. The ILD layer 132 may be formed of silicon oxide (SiO₂) and have a thickness of between about 50 μm and about 500 μm. The masking process in block 214 may include any appropriate deposition process, such as atomic layer deposition (ALD), chemical vapor deposition (CVD), physical vapor deposition (PVD), or the like.

In block 216, a hole patterning process is performed to form a memory hole 108, contact holes 306 in which word line contacts are to be formed, a contact hole 308 in which a common source contact to be formed, and a contact hole 310 in which peripheral contacts are to be formed, through the ILD layer 132, the stacking mold 124, and/or the insulator layer 128, as shown in FIG. 3H. A thickness of the stacking mold 124 may be between about 8 μm and about 21.5 μm, for example, about 14 μm. The memory hole 108 is formed through the ILD layer 132 and the stacking mold 124 in the MH region, and may have a CD of between about 90 nm and about 110 nm (i.e., aspect ratio is between about 73 and about 238). The contact holes 306 are formed through the ILD layer 132, the stacking mold 124 and/or the insulator layer 128 in the WLC region, and may have a CD of between about 150 nm and about 250 nm, for example, about 220 nm (i.e., aspect ratio is between about 32 and about 143, for example, about 64). The contact hole 308 is formed through the ILD layer 132 and the stacking mold 124 in the CSC region, and may have a CD of between 150 nm and 250 nm, for example, about 220 nm (i.e., aspect ratio is between about 32 and about 143, for example, about 64). The contact hole 310 is formed through the ILD layer 132 and the stacking mold 124 in the PeriC region, and may have a CD of between about 250 nm and 400 nm, for example, about 400 nm (i.e., aspect ratio is between about 21 and about 86, for example, about 35).

The hole patterning process in block 216 may include any appropriate lithography and etch processes, such as photolithography.

In some embodiments, to alleviate the difficulty of patterning of holes of high aspect ratio, the processes in the method 200 are performed in multiple steps, in each of which a portion of the stacking mold 124 is formed and the memory hole 108 and the contact holes 306, 308, and 310 are formed through that portion of the stacking mold 124.

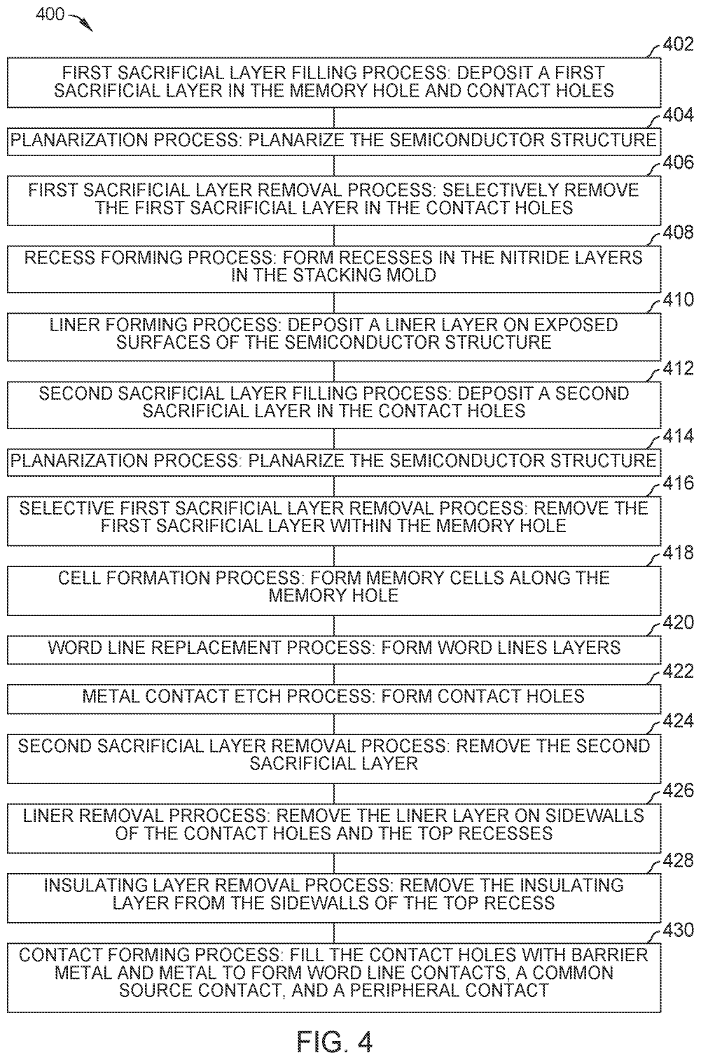

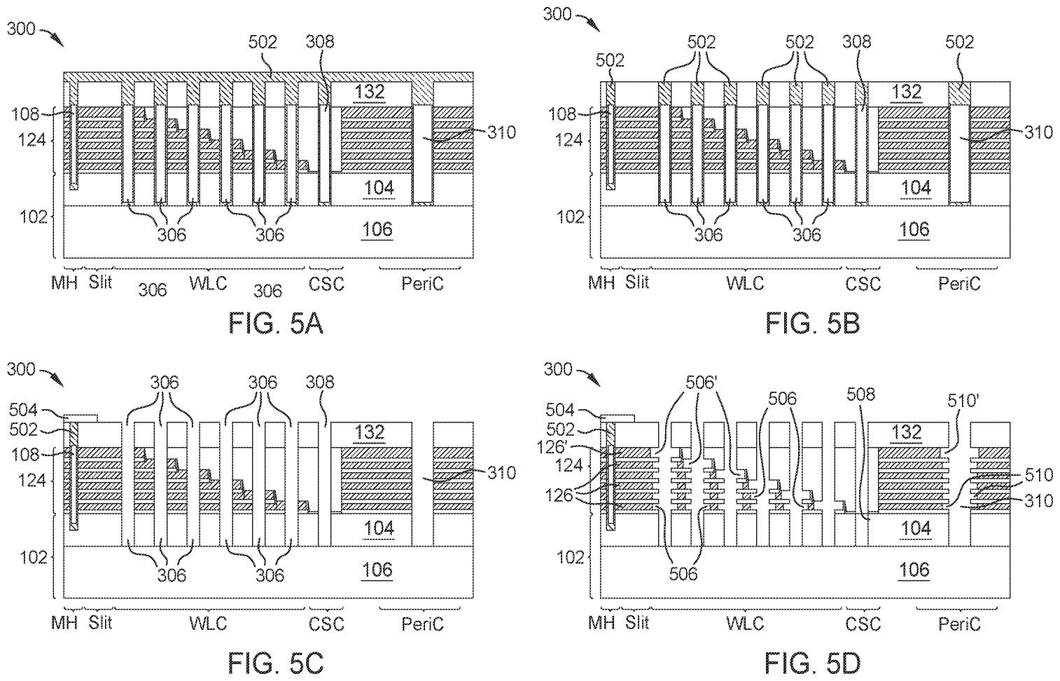

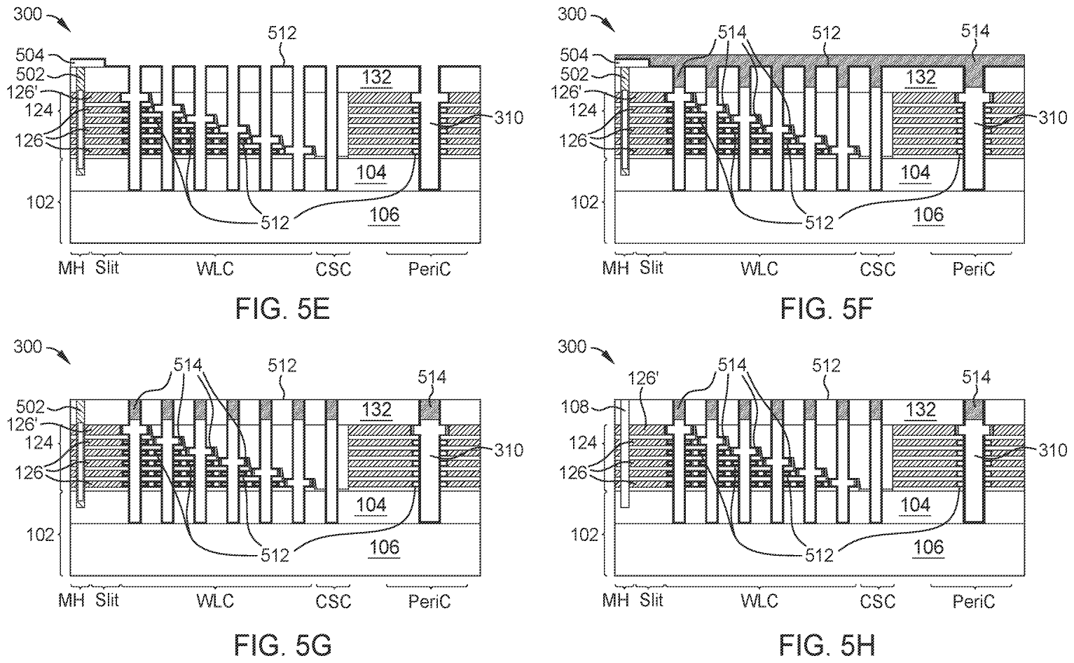

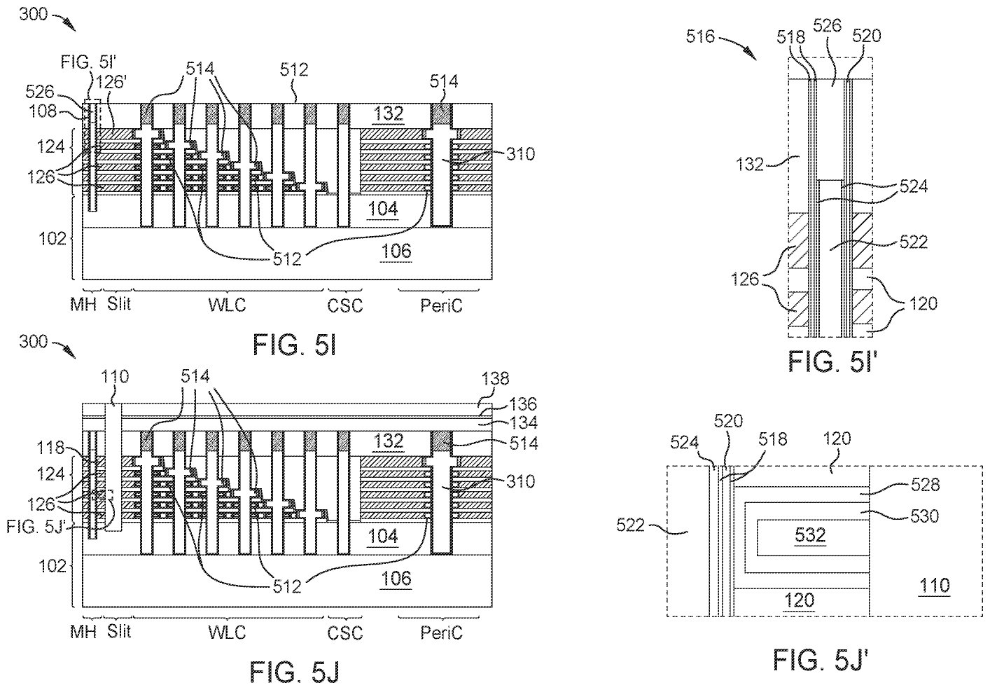

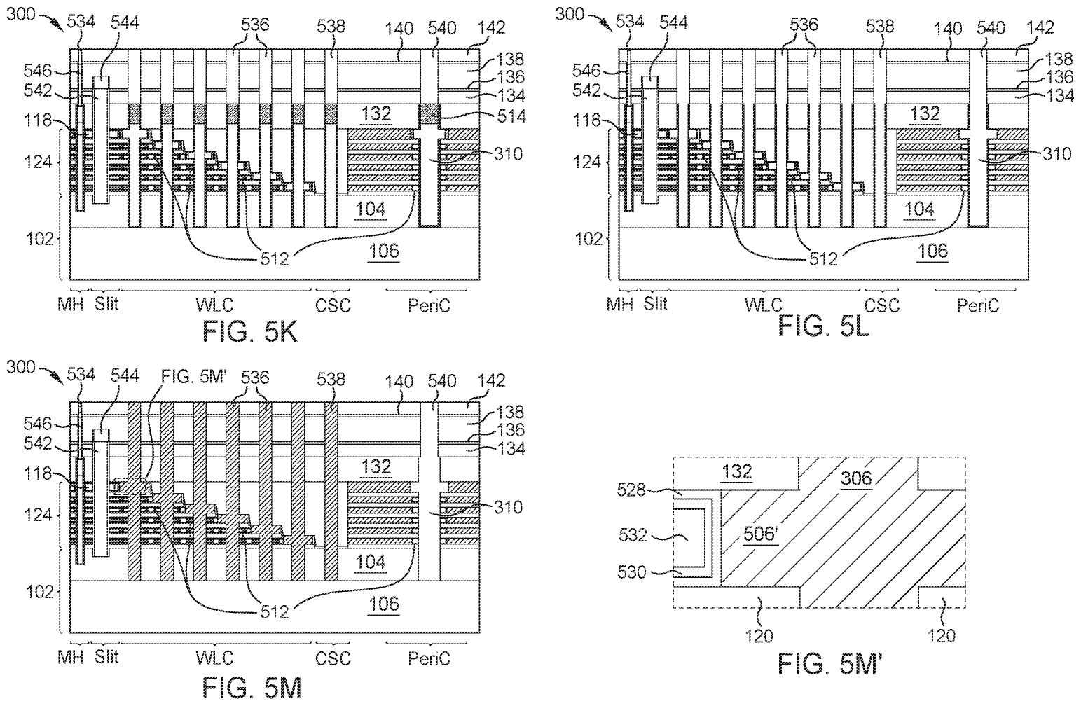

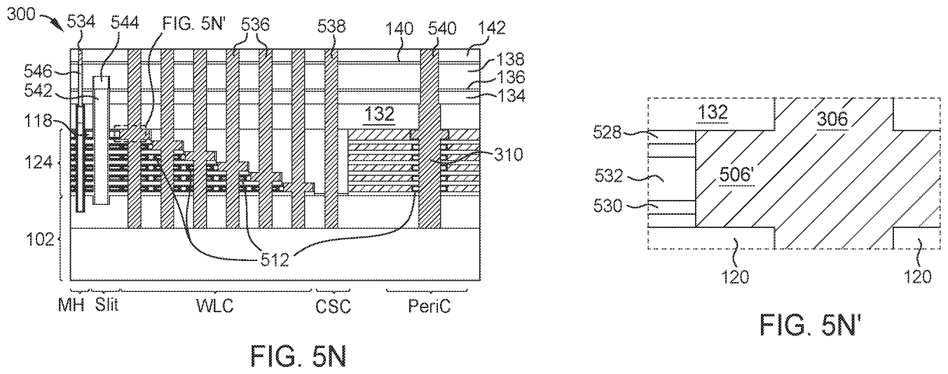

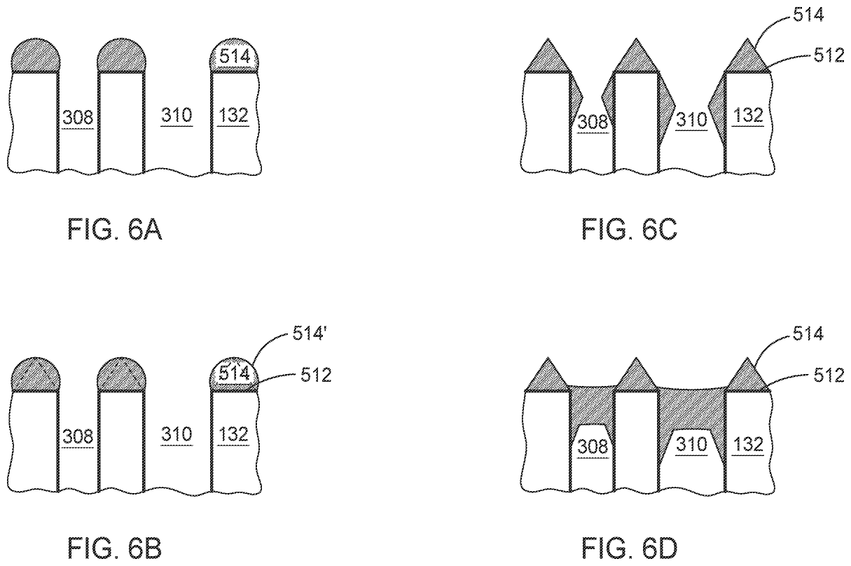

FIG. 4 depicts a process flow diagram of a method 400 for forming a memory hole, word line contacts, and peripheral contacts in the semiconductor structure 300 formed by the method 200. FIGS. 5A, 5B, 5C, 5D, 5E, 5F, 5G, 5H, 5I, 5I′, 5J, 5J′, 5K, 5L, 5M, 5M′, 5N, 5N′, 6A, 6B, 6C, and 6D are cross-sectional views of a portion of the semiconductor structure 300 corresponding to various states of the method 400. It should be understood that FIGS. 5A, 5B, 5C, 5D, 5E, 5F, 5G, 5H, 5I, 5I′, 5J, 5J′, 5K, 5L, 5M, 5M′, 5N, 5N′, 6A, 6B, 6C, and 6D illustrate only partial schematic views of the semiconductor structure 300, and the semiconductor structure 300 may contain any number of transistor sections and additional materials having aspects as illustrated in the figures. It should also be noted that although the method illustrated in FIG. 4 is described sequentially, other process sequences that include one or more operations that have been omitted and/or added, and/or has been rearranged in another desirable order, fall within the scope of the embodiments of the disclosure provided herein.

The method 400 begins with block 402, in which a first sacrificial layer filling process is performed to deposit a first sacrificial layer 502 in the memory hole 108 and the contact holes 306, 308, and 310, as shown in FIG. 5A. The first sacrificial layer 502 may be formed of material that can be filled into high aspect ratio holes, such as the memory holes 108, and has high etch selectivity against silicon nitride (Si₃N₄) and silicon (Si). An example of material for the first sacrificial layer 502 includes carbon (C).

The first sacrificial layer filling process in 402 may include any appropriate deposition process, such as atomic layer deposition (ALD), chemical vapor deposition (CVD), physical vapor deposition (PVD), or the like.

In block 404, a planarization process is performed to planarize the semiconductor structure 300, as shown in FIG. 5B, by use of a chemical mechanical planarization (CMP) process or an etch back of the first sacrificial layer 502.

In block 406, a first sacrificial layer removal process is performed to selectively remove the first sacrificial layer 502 in the contact holes 306 in the WLC region, in the contact hole 308 in the CSC region, and in the contact hole 310 in the PeriC region, as shown in FIG. 5C. In the first sacrificial layer removal process, a mask 504 is deposited over the memory hole 108 in the region MH and the first sacrificial layer 502 in the contact region (i.e., the WLC region, the CSC region, the PeriC region) is removed. The mask 504 may be formed of silicon oxide (SiO₂). The first sacrificial layer 502 formed of carbon (C) can be removed by ashing in an oxidant ambient.

In block 408, a recess forming process is performed to form recesses 506 and 510 in the nitride layers 126 in the stacking mold 124, as shown in FIG. 5D. The recesses 506 are formed from sidewalls of the contact holes 306. The recess 508 is formed from sidewalls of the contact hole 308. The recesses 510 are formed from sidewalls of the contact hole 310. The nitride layers 126 in the stacking mold 124 can be recessed by an etch process using hot phosphorus acid. The recesses 506, 508, and 510 may have a depth of between about 10 nm and about 100 nm. It should be noted that top recesses 506′ along each of the contact holes 306 and a top recess 510′ along the contact hole 310 have an increased height as compared to the remaining recesses 506 and 510, as the top nitride layer 126′ is thicker than the remaining nitride layer, and the exposed portions 126S of the nitride layers 126 are raised by the riser layers 304 (shown in FIGS. 3E and 3F).

In block 410, a liner forming process is performed to deposit a liner layer 512 on exposed surfaces of the semiconductor structure 300, as shown in FIG. 5E. The liner layer 512 may be formed of silicon oxide (SiO₂) and have a thickness of between about a half of T_{N} (thickness of the nitride layers 126) and about a half of TNR (thickness of the raised pad 126S′ the nitride layers 126). Thus, the top recesses 506′ and 510′ are partially filled with the liner layer 512 and the remaining recesses 506 and 510 and the recess 508 are fully filled with the liner layer 512.

The liner layer 512 may be used as an etch stop layer (ESL) in the subsequent etch process in the word replacement process in block 420 and also selective electrical connection of a word line contact to be formed within the contact hole 306 to one word line (at the top of the staircase 122).

The liner forming process in block 410 may include any appropriate deposition process, such as atomic layer deposition (ALD), chemical vapor deposition (CVD), physical vapor deposition (PVD), or the like.

In block 412, a second sacrificial layer filling process is performed to deposit a second sacrificial layer 514 in the contact holes 306, 308, and 310, as shown in FIG. 5F. The second sacrificial layer 514 may be formed of amorphous silicon (a-Si), or other silicon-containing material, such as poly-silicon (Si), pure silicon, carbon (C)-doped silicon, boron (B)-doped silicon, phosphorous (P)-doped silicon, or nitrogen (N)-doped silicon. The second sacrificial layer 514 formed of amorphous silicon (a-Si) may have a thickness of between about 20 nm and about 300 nm, for example, about 150 nm, with a CD ranging from about 180 nm to about 300 nm. The second sacrificial layer 514 formed of poly-silicon (S) may have a thickness of greater than about 200 nm. The second sacrificial layer filling process is a cycle of a deposition process and an etch process that includes a high-density plasma chemical vapor deposition (HDP-CVD) process, and a plasma assisted dry etch process. In the HDP-CVD process, the semiconductor structure 300 is exposed to a deposition gas including silicon-containing precursor, such as silane (SiH₄), disilane (Si₂H₆), tetrasilane (Si₄H₁₀), or a combination thereof. In the plasma assisted dry etch process, the semiconductor structure is exposed to an appropriate etching gas, such as sulphur hexafluoride (SF₆). The HDP-CVD process may be an inductively coupled plasma CVD (ICP-CVD) process, a capacitor coupled plasma CVD (CCP-CVD) process, or a plasma enhanced chemical vapor deposition (PE-CVD) process, performed in a processing system, such as the system 700 described below. The plasma assisted dry etch process may be performed in a processing system as the HDP-CVD process.

The second sacrificial layer filling process may be performed at a process temperature of between about 300° C. and about 500° C. with a chamber pressure of between about 0.1 mTorr and about 100 mTorr, for example, about 20 mTorr at a flow rate of the silicon-containing precursor of between about 20 sccm and about 200 sccm. The etch process partially removes the second sacrificial layer 514 deposited at a top portion of each of the contact holes 306, 308, and 310 such that the second sacrificial layer 514 has a desired shape. For example, in the example shown in FIG. 5F, only the top recesses 506′ and 510′ and above in the contact holes 306 and 310 and a top portion of the contact hole 308 are filled with the second sacrificial layer 514 and the remaining portions of the contact holes 306, 308, and 310 (i.e., below the top recesses 506′ and 510′ are substantially void. The cycle of the deposition process and the etch process may be repeated until a desired thickness of the second sacrificial layer 514 is deposited.

In the deposition process, the second sacrificial layer 514 is deposited on the liner layer 512 over the ILD layer 132 adjacent to the contact holes 306, 308, and 310, as shown in FIG. 6A (only the contact holes 308 and 310 are shown). In the subsequent etch process, portions 514′ of the deposited second sacrificial layer 514 on the liner layer 512 shown in FIG. 6B are removed and re-deposited on inner sidewalls of the contact holes 306, 308, and 310 as shown in FIG. 6C. This cycle of the deposition process and the etch process is repeated until top portions of the contact holes 306, 308 (having a smaller CD of between 150 nm and 250 nm, for example, about 220 nm) and the contact hole 310 (having a larger CD of between about 250 nm and 400 nm, for example, about 400 nm) are simultaneously filled from the top of the contact holes 306, 308, and 310, as shown in FIG. 6D. The contact holes 306, 308, and 310 each have a depth of greater than about 15 μm, and thus bottom portions of the contact holes 306, 308, and 310 are not filled with the second sacrificial layer 514.

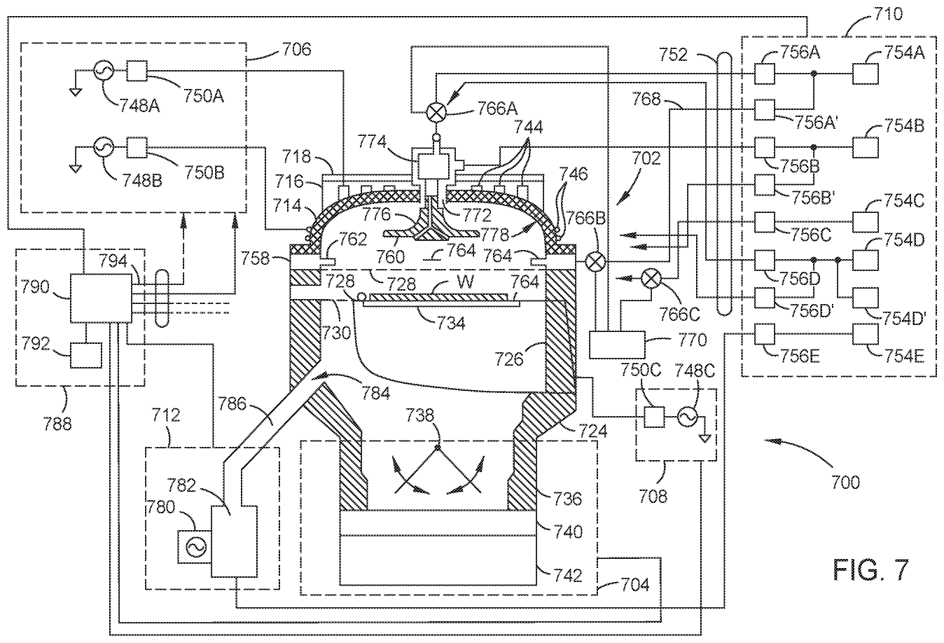

A thickness of the second sacrificial layer 514 can be controlled by adjusting a bias radio frequency (RF) power to a plasma system, such as the bias plasma system 708 shown in FIG. 7, a process temperature, a chamber pressure, and/or a flow rate of the precursor during the cycle of the deposition process and the etch process.

This cycle of the deposition process and the etch process can widen a CD of an opening, such as the contact holes 306, 308, and 310, and further control the CD by adjusting a bias RF power to a plasma system and/or a process temperature during the etch process. The bias RF power may be between about 200 W and about 5000 W. The process temperature may be between about 200° C. and 600° C. A higher bias RF power leads to a larger CD of an opening. A higher process temperature leads to a larger CD of an opening. The inventors have found that an CD of an opening changed from 196 nm at a low bias RF power of about 1000 W, about 264 nm at a medium bias RF power of about 2000 W, and to about 372 nm at a high bias RF power of about 4000 W. The inventors also found that an CD of an opening changed from about 220 nm at a low process temperature of about 300° C. to about 306 nm at a high process temperature of about 500° C. Thus, a tunnel structure may be formed by widening a CD of an opening, which can benefit in the subsequent metal fill process.

The use of amorphous silicon can also benefit in the subsequent removal processes, as amorphous silicon has etch selectivity from carbon (C) (in the first sacrificial layer 502), silicon oxide (SiO₂) (in the dielectric layer 134, the dielectric layer 138, the liner layer 512), and silicon nitride silicon nitride (Si₃N₄) (in the dielectric layer 136).

In block 414, a planarization process is performed to planarize the semiconductor structure 300, as shown in FIG. 5G, by use of a chemical mechanical planarization (CMP) process or an etch back of the second sacrificial layer 514.

In block 416, a selective first sacrificial layer removal process is performed to remove the first sacrificial layer 502 within the memory hole 108 in the MH region, as shown in FIG. 5H. The first sacrificial layer 502 formed of carbon (C) can be removed by ashing in an oxidant ambient with high selectivity against the second sacrificial layer 514 (e.g., silicon (Si)). Thus, only the first sacrificial layer 502 is removed while the second sacrificial layer 514 remains in the selective first sacrificial layer removal process in block 416.

In block 418, a cell formation process is performed to form memory cells 516 along the memory hole 108, as shown in FIGS. 5I and 5I′. A memory cell includes blocking layers 518 formed of silicon oxide (SiO₂), a charge trap layer 520 formed of silicon nitride (Si₃N₄), a tunnel oxide 522 formed of silicon oxide (SiO₂), and a channel 524 formed of poly-silicon (Si). Over the channel 524, a bit line (BL) pad 526 formed poly-silicon (Si) is deposited. The BL pad 526 may be highly doped with n-type dopants.

The cell formation process may include deposition process, such as atomic layer deposition (ALD), chemical vapor deposition (CVD), physical vapor deposition (PVD), or the like, and annealing process in nitrogen (N₂) ambient at a temperature of between about 750° C. and about 1000° C., for example, 800° C., for a duration of between about 1 hour and about 2 hours. The second sacrificial layer 514 formed of silicon-containing material is thermally stable at this temperature.

In block 420, a word line replacement process is performed to form word lines layers 118, as shown in FIGS. 5J and 5J′. In block 420, a dielectric layer 134, a dielectric layer 136, and a dielectric layer 138 are deposited on the exposed surface of the semiconductor structure 300, and a gate slit line 110 is formed through the dielectric layers 134, 136, and 138 and the stacking mold 124. The dielectric layers 134 and 138 may be formed of silicon oxide (SiO₂). The dielectric layer 136 may be formed of silicon nitride (Si₃N₄) and act as a chemical mechanical planarization (CMP) stop layer. From the gate slit line 110, the nitride layers 126 in the stacking mold 124 are removed and the resulting openings are filled with an insulating layer 528 formed of aluminum oxide (Al₂O₃), a barrier layer 530 formed of titanium nitride (TiN), and a metal layer 532 formed of tungsten (W) are formed.

The word line replacement process may include any appropriate lithography and etch processes, such as photolithography, to form the gate slit line 110, an etch process using hot phosphorus acid to remove nitride layers 126 in the stacking mold 124, and appropriate deposition process, such as atomic layer deposition (ALD), chemical vapor deposition (CVD), physical vapor deposition (PVD), or the like to deposit the insulating layer 528, the barrier layer 530, and the metal layer 532.

In block 422, a metal contact etch process is performed to form contact holes 534, 536, 538, and 540, as shown in FIG. 5K. Prior to forming the contact holes 534, 536, 538, and 540, the gate slit line 110 is filled with a poly-silicon (Si) layer 542, and further filled with a metal layer 544. The memory hole 108 is further filled with a metal layer 546. Further, a dielectric layer 140 and a dielectric layer 142 are deposited on the exposed surface of the semiconductor structure 300. The dielectric layer 142 may be formed of silicon oxide (SiO₂). The dielectric layer 140 may be formed of silicon nitride (Si₃N₄) and act as a chemical mechanical planarization (CMP) stop layer. The contact hole 534 connecting to the memory hole 108 is formed through the dielectric layer 142 in the MH region. The contact holes 536 connecting to the contact holes 306 are formed through the dielectric layers 134, 136, 138, 140, and 142, the stacking mold 124, and the CSL layer 104 in the WLC region. The contact hole 538 connecting to the contact hole 308 is formed through the dielectric layers 134, 136, 138, 140, and 142, the stacking mold 124, and the CSL layer 104 in the CSC region. The contact hole 540 connecting to the contact hole 310 is formed through the dielectric layers 134, 136, 138, 140, and 142, the stacking mold 124, and the CSL layer 104 in the PeriC region.

The metal contact etch process in block 422 may include any appropriate lithography and etch processes, such as photolithography.

In block 424, a second sacrificial layer removal process is performed to remove the second sacrificial layer 514, as shown in FIG. 5L. The second sacrificial layer 514 (e.g., silicon (Si)) in the WLC region and the PeriC region may be removed by an etch process using tetramethyl ammonium hydroxide (TMAH, (CH₃)₄NOH) with high etch selectivity against tungsten (W), silicon nitride (Si₃N₄), and silicon oxide (SiO₂). Thus, the word line layers 118 remain unetched.

In block 426, a liner removal process is performed to remove the liner layer 512 on sidewalls of the contact holes 306 and the top recesses 506′ in the WLC region and sidewalls of the contact hole 310 and the top recess 510′ in the PeriC region, as shown in FIGS. 5M and 5M′. The liner removal process in block 426 may include an etch process using hydrofluoric acid (HF) solution.

In block 428, an insulating layer removal process is performed to remove the insulating layer 528 from the sidewalls of the top recess 506′, as shown in FIGS. 5N and 5N′. The insulating layer removal process in block 428 may include an etch process using hot phosphorus acid or an anisotropic etch process such as reactive ion etching (RIE).

In block 430, a contact forming process is performed to fill the contact holes 534, 536, 538, and 540 with barrier metal, such as titanium nitride (TiN), and metal, such as tungsten (W), to form word line contacts 112, a common source contact 114, and a peripheral contact 116, as shown in FIG. 1. Subsequently, conventional back end of line (BEOL) processes are followed.

FIG. 7 is a schematic view of an exemplary HDP-CVD system 700 according to one embodiment, that can be used to perform HDP-CVD processes in the method 400. The system 700 includes a chamber 702, a vacuum system 704, a source plasma system 706, a bias plasma system 708, a gas delivery system 710, and a remote plasma cleaning system 712.

The upper portion of chamber 702 includes a dome 714, which is made of a ceramic dielectric material, such as aluminum oxide or aluminum nitride, sapphire, SiC or quartz. A heater plate 716 and a cold plate 718 surmount, and are thermally coupled to, the dome 714. The heater plate 716 and the cold plate 718 allow control of the dome temperature to within about ±10° C. over a range of about 100° C. to 200° C. The dome 714 defines an upper boundary of a plasma processing region 720. The plasma processing region 720 is bounded on the bottom by the upper surface of a substrate W and a substrate support 722.

The lower portion of chamber 702 includes a chamber body 724, which joins the chamber to the vacuum system 704. A base portion 726 of the substrate support 722 is mounted on, and forms a continuous inner surface with, the chamber body 724. Substrates are transferred into and out of the chamber 702 by a robot blade (not shown) through an insertion/removal opening (not shown) in the side of the chamber 702. Lift pins (not shown) are raised and then lowered under the control of a motor (also not shown) to move the substrate W from the robot blade at an upper loading position 728 to a lower processing position 730 in which the substrate W is placed on a substrate receiving portion 732 of the substrate support 722. The substrate receiving portion 732 includes an electrostatic chuck 734 that secures the substrate W to the substrate support 722 during substrate processing.

The vacuum system 704 includes a throttle body 736, which houses a twin-blade throttle valve 738 and is attached to a gate valve 740 and a turbo-molecular pump 742. It should be noted that the throttle body 736 offers minimum obstruction to gas flow, and allows symmetric pumping. The gate valve 740 can isolate the turbo-molecular pump 742 from the throttle body 736, and can also control chamber pressure by restricting the exhaust flow capacity when the throttle valve 738 is fully open. The arrangement of the throttle valve 738, the gate valve 740, and the turbo-molecular pump 742 allow accurate and stable control of chamber pressures from between about 0.1 mTorr to about 2 Torr.

The source plasma system 706 includes a top coil 744 and a side coil 746, mounted on dome 714. A symmetrical ground shield (not shown) reduces electrical coupling between the coils 744 and 746. The top coil 744 is powered by a top source RF generator 748A, whereas the side coil 746 is powered by a side source RF generator 748B, allowing independent power levels and frequencies of operation for each coil. This dual coil system allows control of the radial ion density in the chamber 702, thereby improving plasma uniformity. The side coil 746 and the top coil 744 are typically inductively driven, which does not require a complimentary electrode. In a specific embodiment, the top source RF generator 748A provides up to 2,500 watts of RF power at nominally 2 MHz and the side source RF generator 748B provides up to 5,000 watts of RF power at nominally 2 MHz. The operating frequencies of the top source RF generator 748A and the side source RF generator 748B may be offset from the nominal operating frequency (e.g., to 1.7-1.9 MHz and 1.9-2.1 MHz, respectively) to improve plasma-generation efficiency. In many embodiments, the top and side coils can be cooled by a liquid.

The bias plasma system 708 includes a bias RF generator 748C and a bias matching network 750C. The bias plasma system 708 capacitively couples the plasma processing region 720 to the chamber body 724, which act as complimentary electrodes. The bias plasma system 708 serves to enhance the transport of plasma species (e.g., ions) created by the source plasma system 706 to the surface of the substrate. In a specific embodiment, the bias RF generator 748C provides up to 5,000 watts of RF power at 13.56 MHz.

The source RF generators 748A and 748B include digitally controlled synthesizers and operate over a frequency range between about 1.8 to about 2.1 MHz. Each of the source RF generators 748A and 748B includes an RF control circuit (not shown) that measures reflected power from the chamber 702 and coil back to the source RF generator 748A and 748B and adjusts the frequency of operation to obtain the lowest reflected power, as understood by a person of ordinary skill in the art. The source RF generators 748A and 748B are typically designed to operate into a load with a characteristic impedance of 50 ohms. RF power may be reflected from loads that have a different characteristic impedance than the source RF generator 748A and 748B. This can reduce power transferred to the load. Additionally, power reflected from the load back to the source RF generator 748A and 748B may overload and damage the source RF generators 748A and 748B. Because the impedance of a plasma may range from less than 5 ohms to over 900 ohms, depending on the plasma ion density, among other factors, and because reflected power may be a function of frequency, adjusting the generator frequency according to the reflected power increases the power transferred from the source RF generator 748A and 748B to the plasma and protects the source RF generator 748A and 748B. Another way to reduce reflected power and improve efficiency is with a matching network.

Matching networks 750A and 750B match the output impedance of the generators 748A and 748B with the top coil 744 and the side coil 746, respectively. The RF control circuit may tune both of the matching networks 750A and 750B by changing the value of capacitors within the matching networks 750A and 750B to match the source RF generators 748A and 748B to the load as the load changes. The RF control circuit may tune a matching network 750A or 750B when the power reflected from the load back to the corresponding source RF generator 748A or 748B exceeds a certain limit. One way to provide a constant match, and effectively disable the RF control circuit from tuning the matching network 750A or 750B, is to set the reflected power limit above any expected value of reflected power. This may help stabilize a plasma under some conditions by holding the matching network constant at its most recent condition.

Other measures may also help stabilize a plasma. For example, the RF control circuit can be used to determine the power delivered to the load (plasma) and may increase or decrease the generator output power to keep the delivered power substantially constant during deposition of a layer.

The gas delivery system 710 provides gases from several sources to the chamber 702 for processing the substrate via gas delivery lines 752 (only some of which are shown). As would be understood by a person of skill in the art, the actual sources used and the actual connection of the gas delivery lines 752 to the chamber 702 varies depending on the deposition and cleaning processes executed within the chamber 702. Gases are introduced into the chamber 702 through a gas ring 758 and/or a gas distributor 760. In one embodiment, a first gas source 754A, a second gas source 7546, a multifunction gas flow controller 756A′ and a multifunction gas flow controller 7566′, provide gas to a ring plenum in the gas ring 758 via gas the gas delivery lines 752 (only some of which are shown). The gas ring 758 has source gas nozzles 762 (only one of which is shown for purposes of illustration) that provide a uniform flow of gas over the substrate. Nozzle length and nozzle angle may be changed to allow tailoring of the uniformity profile and gas utilization efficiency for a particular process within an individual chamber.

The gas ring 758 also has oxidizer gas nozzles 764 (only one of which is shown). In one embodiment, a third gas source 754C, a fourth gas source 754D, a fifth gas source 754D′, a gas flow controller 756C and a multifunction gas flow controller 756D, provide gas to body plenum via gas the gas delivery lines 752. Additional valves, such as a valve 7666, may shut off gas from the flow controllers to the chamber 702.

In embodiments where flammable, toxic, or corrosive gases are used, it may be desirable to eliminate gas remaining in the gas delivery lines after a deposition. This may be accomplished using a 3-way valve, such as the valve 7666, to isolate the chamber 702 from a delivery line 768 and to vent the delivery line 768 to a vacuum foreline 770, for example. As shown in FIG. 7, other similar valves, such as a valve 766A and a valve 766C, may be incorporated on other gas delivery lines. For example, the multifunction gas flow controller 756D can be connected to the valve 766A to provide gases gas from the fourth gas source 754D and the fifth gas source 754D′ to the chamber 702.

The chamber 702 also has the gas distributor 760 and a top vent 772. The gas distributor 760 and the top vent 772 allow independent control of top and side flows of the gases. The top vent 772 is an annular opening around the gas distributor 760. In one embodiment, the first gas source 754A supplies the source gas nozzles 762 and the gas distributor 760. The multifunction gas flow controller 756A′ controls the amount of gas delivered to the source gas nozzles 762 and a top nozzle multifunction gas flow controller 756A controls the amount of gas delivered to gas distributor 760. Similarly, a multifunction gas flow controller 756B and the multifunction gas flow controller 756B′ may be used to control the flow of oxygen to both the top vent 772 and the oxidizer gas nozzles 764 from a single source of oxygen, such as the second gas source 754B. The gases supplied to gas distributor 760 and the top vent 772 may be kept separate prior to flowing the gases into the chamber 702, or the gases may be mixed in a top plenum 774 before they flow into the chamber 702. Separate sources of the same gas may be used to supply various portions of the chamber 702.

The gas distributor 760 comprises a gas baffle 776. The gas baffle 776 is formed on the gas distributor 760 to direct flows of clean gas toward the chamber wall and can also be used to direct flows of remotely generated plasma and clean gas. The gas distributor includes separate channels that pass separate gases into the chamber 702 where the gases mix and react above a substrate.

To prevent contamination during deposition of a dielectric layer on a wafer, chamber 702 can seasoned with a protective coating 778 that also covers the gas distributor 760. The protective coating 778, for example SiO₂, can cover structures inside the chamber 702.

The remote plasma cleaning system 712 is provided to periodically clean deposition residues from chamber components. The remote plasma cleaning system 712 includes a remote microwave generator 780 that creates a plasma from a cleaning gas source 754E (e.g., molecular fluorine, nitrogen trifluoride, other fluorocarbons or equivalents) in a reactor cavity 782. In some embodiments, a gas flow controller 756E controls the flow of gas from cleaning gas source 754E to the reactor cavity 782. The reactive species resulting from this plasma are conveyed to the chamber 702 through a cleaning gas feed port 784 via an applicator tube 786. Generating the cleaning plasma in a remote cavity allows the use of an efficient microwave generator and does not subject chamber components to the temperature, radiation, or bombardment of the glow discharge that may be present in a plasma formed in situ.

A system controller 788, such as a programmable computer, is coupled to the system 700. The system controller 788 includes a programmable central processing unit (CPU) 790, which is operable with a memory 792 (e.g., non-volatile memory) and support circuits 794. The support circuits 794 (e.g., cache, clock circuits, input/output subsystems, power supplies, etc., and combinations thereof) are conventionally coupled to the CPU 790 and coupled to the various components of the system 700.

The system controller 788 may control the operation of the system 700 using direct control of the vacuum system 704, the source plasma system 706, the bias plasma system 708, the gas delivery system 710, and the remote plasma cleaning system 712. The system controller 788 separately controls each of the gas flow controllers and the multifunction gas flow controllers. It will be understood that the system controller 788 can include several distributed processors to control the components of the system 700. The source plasma system 706 is connected to the top coil 744 and the side coil 746 so that the top coil voltage and the side coil voltage can be controlled by the system controller 788.

The embodiments described herein provide methods for forming different types of high aspect ratio contacts (HARCs) in three-dimensional (3D) NAND memory devices. The methods include covering memory holes with a carbon-containing sacrificial layer, covering other contact holes with a silicon-containing sacrificial layer, removing the carbon-containing sacrificial layer and forming memory cells along the memory holes. The silicon-containing sacrificial layer is thermally stable during fabrication of memory cells that requires a high temperature anneal. The silicon-containing sacrificial layer is formed by a deposition/etch/deposition (DED) process, including a high density plasma chemical vapor deposition (HPD CVD) process, such that the sacrificial layer covers top portions of the contact holes. The methods described herein allow fabrication of different types of HARCs together, and thus reduce fabrication cost of 3D NAND memory devices.

The sacrificial layer formed of silicon (e.g., amorphous silicon) used to fill holes for word line contacts and peripheral contacts has etch selectivity from a carbon (C)-containing sacrificial layer used fill memory holes, dielectric layers (e.g., silicon oxide (SiO₂) or silicon nitride (Si₃N₄), or metal layers (e.g., tungsten (W)).

While the foregoing is directed to embodiments of the present disclosure, other and further embodiments of the disclosure may be devised without departing from the basic scope thereof, and the scope thereof is determined by the claims that follow.

1. A method of forming a semiconductor memory device, comprising:
simultaneously filling a top portion of a first high aspect ratio (HAR) structure and a top portion a second HAR structure with a silicon-containing sacrificial layer by a cycle of a deposition process and an etch process,
wherein the first HAR structure has a critical dimension (CD) of between 150 nm and 250 nm, and the second HAR structure has a CD of between 250 nm and 400 nm.

2. The method of claim 1, wherein the deposition process comprises a high-density plasma chemical vapor deposition (HDP-CVD) process.

3. The method of claim 1, wherein the silicon-containing sacrificial layer comprises amorphous silicon.

4. The method of claim 1, wherein the first HAR structure is a contact hole in which a word line contact is to be formed or a contact hole in which a common source contact is to be formed, and the second HAR structure is a contact hole in which a peripheral contact is to be formed.

5. The method of claim 1, wherein
the first HAR structure and the second HAR structure each have a depth of greater than 15 μm,
the silicon-containing sacrificial layer has a thickness of between 20 nm and 300 nm, and
a bottom portion of the first HAR structure and a bottom portion of the second HAR structure are not filled with the silicon-containing sacrificial layer.

6. The method of claim 1, further comprising:
selectively removing a carbon-containing sacrificial layer filled in a memory hole.

7. The method of claim 1, further comprising:
removing the silicon-containing sacrificial layer selectively to a silicon oxide (SiO₂)-containing liner layer formed on inner sidewalls of the first HAR structure.

8. A method of forming a semiconductor memory device, comprising:
filing a top portion of a high aspect ratio (HAR) opening with a silicon-containing sacrificial layer by a cycle of a deposition process and an etch process; and
widening a critical dimension (CD) of the HAR opening.

9. The method of claim 8, wherein
the deposition process in the cycle comprises a high-density plasma chemical vapor deposition (HDP-CVD) process using a plasma system; and
the etch process in the cycle comprises a plasma assisted dry etch process using the plasma system.

10. The method of claim 9, wherein
the widening the CD of the HAR opening comprises adjusting a bias radio frequency (RF) power to the plasma system and an process temperature.

11. The method of claim 10, wherein the bias RF power is between 200 W and 5000 W.

12. The method of claim 10, wherein the process temperature is between 200° C. and 600° C.

13. The method of claim 9, wherein
a chamber pressure during the HDP-CVD process and the plasma assisted dry etch process is between 0.1 mTorr and 100 mTorr.

14. The method of claim 9, wherein
a flow rate of a silicon-containing precursor used in the HDP-CVD process is between 20 sccm and 200 sccm.

15. A method of forming a semiconductor memory device, comprising:
performing a hole patterning process, the hole patterning process comprising forming a memory hole and contact holes through a stacking mold of alternating oxide layers and nitride layers;
performing a first filling process, the first filling process comprising filling the memory hole and the contact holes with a carbon-containing sacrificial layer;
performing a first removal process, the first removal process comprising selectively removing the carbon-containing sacrificial layers from the contact holes;
performing a second filling process, the second filling process comprising filling the contact holes with an amorphous silicon-containing sacrificial layer; and
performing a cell formation process, the cell formation process comprising forming memory cells along the memory hole.

16. The method of claim 15, wherein the second filling process comprises a high-density plasma chemical vapor deposition (HDP-CVD) process and an etch process.

17. The method of claim 15, wherein the cell formation process comprising depositing and annealing blocking layers comprising silicon oxide (SiO₂), a charge trap layer comprising silicon nitride (Si₃N₄), a tunnel oxide comprising silicon oxide (SiO₂), and a channel comprising poly-silicon (Si).

18. The method of claim 15, wherein the first removal process comprises ashing in an oxidant ambient.

19. The method of claim 15, further comprising:
performing a second removal process, the second removal process comprising removing the amorphous silicon-containing sacrificial layer from the contact holes; and
performing a contact forming process, the contact forming process comprising filling the contact holes with barrier metal and metal.

20. The method of claim 19, wherein the second removal process comprises an etch process using tetramethyl ammonium hydroxide (TMAH, (CH₃)₄NOH).
